(19) United States
(12) Patent Application Publication
(10) Pub. No.: US 2013/0119489 A1
(43) Pub. Date: May 16, 2013

(54) METHOD AND APPARATUS FOR WAFER-LEVEL SOLDER HERMETIC SEAL ENCAPSULATION OF MEMS DEVICES

(71) Applicants: Tallis Y. Chang, San Diego, CA (US); Yaoling Pan, San Diego, CA (US); John H. Hong, San Diego, CA (US); Chong U. Lee, San Diego, CA (US)

(72) Inventors: Tallis Y. Chang, San Diego, CA (US); Yaoling Pan, San Diego, CA (US); John H. Hong, San Diego, CA (US); Chong U. Lee, San Diego, CA (US)

(73) Assignee: QUALCOMM Incorporated, San Diego, CA (US)

(21) Appl. No.: 13/294,831

(22) Filed: Nov. 11, 2011

(51) Int. Cl. H01L 31/18; H01L 31/0203

(52) U.S. Cl. 257/415; 438/51; 257/E31.117

(57) ABSTRACT

A plurality of MEMS devices are formed on a substrate, a sacrificial layer is formed to cover each of the MEMS devices and a protective cap layer is formed on the sacrificial layer. A release hole is formed through the protective cap layer to the underlying sacrificial layer, and a releasing agent is introduced through the release hole to remove the sacrificial layer under the protective cap layer and expose a MEMS device. Optionally, the MEMS device can be released with the same releasing agent or, optionally, with a secondary releasing agent. The release hole is solder sealed, to form a hermetic seal of the MEMS device. Optionally, release holes are formed at a plurality of locations, each over a MEMS device and the releasing forms a plurality of hermetic sealed MEMS devices on the wafer substrate, which are singulated to form separate hermetically sealed MEMS devices.

### FIELD OF DISCLOSURE

The present disclosure pertains to packaging of micro devices and, more specifically, to hermetic packaging of micro-electronic and microelectromechanical (MEMS) devices.

### BACKGROUND

MEMS devices include micro mechanical elements, micro electromechanical actuators and related electrical circuitry created using deposition of material layers on substrates, and etching or other micromachining processes that remove portions of the substrates and/or the deposited material layers, and further adding layers to form various electrical and electromechanical devices. MEMS devices have a wide range of applications, and it would be beneficial in the art to utilize and/or modify the characteristics of these types of devices so that their features can be exploited in improving existing products and creating new products that have not yet been developed.

MEMS devices, however, can have particular packaging requirements. For example, certain MEMS devices may perform optimally in a particular ambient state, such as a particular range of humidity or pressure, or in an inert gas. Further, certain MEMS devices can be susceptible to particulate contamination. Protective packaging methods and structures are known, for example a cover substrate may be installed over the MEMS devices. One example cover substrate is a dome or hat-shaped “cap” that can be positioned over each MEMS device and then secured to the supporting substrate. The MEMS devices can be individually packaged, for example in a case, at the chip-level, after being singulated. The cases can be hermetically sealable. However, this adds cost, due to an inherently large number of packaging steps, in addition to increasing the overall dimensions of the device. Further, chip-level packaging for MEMS devices must use means to mitigate problems associated with particles generated from the singulation process. In addition, if a hermetic seal is desired, the bond between the cap and the substrate must be carefully formed to obtain the quality and uniformity of adhesion that is necessary for such sealing.

For reasons as described above a need has existed for economical, reliable wafer-level packaging of MEMS devices, prior to singulation.

### SUMMARY

Exemplary embodiments provide, among other features and benefits, high yield in the hermetic sealing of MEMS devices, without structural complexity and without necessitating significant added fabrication steps. Exemplary embodiments further provide an easily controlled process for hermetic sealing of MEMS devices, with process parameters readily selected and optimized for particular applications.

One method according to one exemplary embodiment can provide hermetic sealing of an opening at an exterior surface of a device to an interior volume of the device, and can include forming a wetting surface on a region of the exterior surface of the device adjacent the opening, and immersing the wetting surface into a viscous fluid to draw a portion of the viscous fluid sufficient to cover and hermetically seal the opening.

In an aspect, the device can include a cap having an interior surface facing the interior volume and the opening can be a port extending through the cap to the interior volume.

One method according to one exemplary embodiment can provide packaging of a device supported on a substrate, and can include forming a device on a wafer-level substrate, forming a sacrificial layer over the device, forming a protective layer over the sacrificial layer, forming a solder-sealable release hole through the protective layer to the sacrificial layer, forming a ported cap from a portion of the protective layer proximal to the release hole, by introducing a releasing agent through the release hole to remove sacrificial layer material under the release hole to form a space under the portion of the protective layer; and solder sealing the release hole to form a hermetically sealed cap covering the space.

In an aspect, one method according to the one exemplary embodiment can include forming the solder-sealable release hole by forming a wetting surface on an exposed surface of the protective layer, and forming a release hole through the protective layer to the sacrificial layer, in an alignment with the wetting surface.

In a further aspect, one method according to the one exemplary embodiment can include, in forming a device on a wafer-level substrate, a forming of a plurality of devices on the wafer-level substrate, and in one still further aspect can include in forming the protective layer a forming of the protective layer to have a plurality of protective cap layer regions, each protective cap layer region overlaying corresponding portion of the sacrificial layer over a corresponding one or more of the devices.

In one related aspect of one method according to the one exemplary embodiment, forming a solder-sealable release hole can include forming at least one solder-sealable release hole through each of the protective cap layer regions to the sacrificial layer, and forming the ported cap can include forming a plurality of ported caps, each having a portion of one of the protective cap layer regions proximal to a corresponding one or more of the solder-sealable release holes.

In another related aspect of one method according to the one exemplary embodiment, the solder sealing can include sealing each of the solder-sealable release holes at each of the plurality of the ported caps to form a corresponding plurality of hermetically sealed caps, each covering a corresponding space.

One exemplary embodiment can provide a releasable and hermitically sealable wafer-level apparatus that can include a plurality of devices supported on the substrate, a sacrificial layer formed on and covering each of the plurality of devices, a protective cap layer formed on the sacrificial layer to extend over at least one of the devices, and having an exposed surface, the protective cap layer including a release hole extending from an opening on the exposed surface to the sacrificial layer, and a wetting surface on the exposed surface, surrounding the opening of the release hole.

In an aspect, at least one of the devices over which the sacrificial layer extends can be a MEMS device.

One exemplary embodiment can provide a wafer-level apparatus that can include a wafer-level substrate, a plurality of devices supported on the wafer-level substrate, and at least one protective cap defining a hermetically sealed space for a corresponding one or more of the devices, and each protective cap can have a peripheral base surrounding the corresponding one or more of the devices and that is deposition bonded to the wafer-level substrate.

In an aspect according to one or more exemplary embodiments, each protective cap can have a cap region extending from the peripheral base and above the corresponding one or more of the devices.

In a further aspect according to one or more exemplary embodiments, each cap region can form a release hole and, further, each cap region can have an external surface supporting a wetting surface proximal to the release hole and a solder bump seal solder bonded to the wetting surface.

### BRIEF DESCRIPTION OF THE DRAWINGS

The accompanying drawings are presented to aid in the description of embodiments of the invention and are provided solely for illustration of the embodiments and not limitation thereof

FIG. 1A is a side, cross-sectional view of one example wafer substrate supporting a plurality of MEMS devices, from a projection normal to the major surface plane of the wafer substrate, in example one process and apparatus according to at least one exemplary embodiment.

FIG. 1B is a top view, from the FIG. 1A projection 1B-1B, of the FIG. 1A example wafer substrate supporting a plurality of MEMS devices in one process and apparatus according to at least one exemplary embodiment.

FIG. 2A is a cross-sectional view, from the FIG. 1A projection 1B-1B, showing a sacrificial layer overlaying a plurality of MEMS devices on a wafer substrate, in an example process and related apparatus according to at least one exemplary embodiment.

FIG. 2B is a cross-sectional view, from the same projection as FIG. 2A, showing singulation reliefs forming the sacrificial layer into sacrificial layer caps, each overlaying one or more of the MEMS devices in an example process and related apparatus according to at least one exemplary embodiment.

FIG. 2C is a cross-sectional view, from the same projection as FIG. 2B, showing a protective cap layer having a plurality of protective cap regions, each protective cap region overlaying a sacrificial layer cap, in an example process and related apparatus according to at least one exemplary embodiment.

FIG. 2D is a cross-sectional view, from the same projection as FIG. 2C, showing an example solder bump promoting structure (wetting surface) at each of a plurality of release hole locations on the protective cap regions of the protective cap layer, in an example process and related apparatus according to at least one exemplary embodiment.

FIG. 2E is a cross-sectional view, from the same projection as FIG. 2D, showing example solder-sealable release holes through the protective cap layer, at release hole locations on the protective cap regions, each solder-sealable release hole extending through the protective cap layer into the underlying sacrificial layer cap, in an example process and related apparatus according to at least one exemplary embodiment.

FIG. 2F is cross-sectional view, from the same projection as FIG. 2E, showing solder-sealable ported caps, each covering and spaced above at least one MEMS device on the wafer substrate, obtained by removing the sacrificial cap material under the release holes, in example process and related apparatus according to at least one exemplary embodiment.

FIG. 2G is a cross-sectional view, from the same projection as FIG. 2F, of a plurality of non-singulated hermetically sealed MEMS devices supported on the wafer substrate, obtained from a solder sealing of the release holes of the solder-sealable protective caps, in an example process and related apparatus according to at least one exemplary embodiment.

FIG. 2H is a cross-sectional view, from the same projection as FIG. 2G, of a plurality of hermetically sealed MEMS devices, obtained from a singulation process on the non-singulated hermetically MEMS devices supported on a common wafer substrate, in an example process and related apparatus according to at least one exemplary embodiment.

FIG. 3 is a top view, from FIG. 2F projection 3-3, of example solder bump promoting structures formed on a protective cap layer overlaying an in-process MEMS structure, in an example process and structure according to at least one exemplary embodiment.

FIGS. 4A, 4B, and 4C show, respectively, an example starting position, solder immersion position, and ending position in an example process employing liquid solder bath sealing of a release hole ported, in-process wafer-level MEMS structure, according to one or more exemplary embodiments.

FIG. 5A is a cross-sectional view, from the FIG. 1A projection 1B-1B, showing one example in-process wafer-level MEMS structure obtained from an aspect of forming, in an example process and related apparatus according to another exemplary embodiment, at least one sacrificial layer overlaying the FIG. 1A-1B example plurality of MEMS devices on a wafer substrate.

FIG. 5B is a cross-sectional view, from the same projection as FIG. 5A, showing one example common protective cap layer overlaying the common sacrificial layer, in an example process and related apparatus according to another exemplary embodiment.

FIG. 5C is a cross-sectional view, from the same projection as FIG. 5B, showing example solder bump promoting structures (wetting surfaces) on the common protective cap layer overlaying the common sacrificial layer, in an example process and related apparatus according to at least one exemplary embodiment.

FIG. 5D is a cross-sectional view, from the same projection as FIG. 5C, showing solder-sealable release holes through the common protective cap layer to the underlying common sacrificial layer over the plurality of MEMS devices on a wafer substrate, in an example process and related apparatus according to at least one exemplary embodiment.

FIG. 5E is cross-sectional view, from the same projection as FIG. 5D, showing a wafer-level protective cap obtained from a releasing operation through the release holes, removing the common sacrificial layer under the common protective cap layer, in an example process and related apparatus according to at least one exemplary embodiment.

FIG. 5F is a cross-sectional view, from the same projection as FIG. 5E, of one example hermetically sealed wafer level MEMS device, obtained from a solder sealing according to at least one exemplary embodiment of the solder-sealable release holes, in an example process and related apparatus according to at least one exemplary embodiment.

FIG. 6 is a top view, from FIG. 5E projection 6-6, of example solder bump promoting structures on a protective cap layer overlaying an in-process MEMS structure, in an example process and structure according to at least one exemplary embodiment.

FIG. 7A is cross-sectional view of an example in-process wafer-level MEMS structure in an example process and related apparatus according to at least one exemplary embodiment, from a projection normal to a major plane of a wafer substrate supporting a plurality of MEMS devices, with a common sacrificial layer cap overlaying a sub-plurality of the MEMS devices, another sacrificial layer overlaying another of the MEMS devices, a common protective cap layer overlaying the common sacrificial layer and another protective cap layer overlaying the other sacrificial layer, with at least one solder-sealable release hole extending through the common protective cap layer to its underlying common sacrificial layer, and at least one solder-sealable release hole extending through the other protective cap layer to its underlying sacrificial layer, in an example process and related apparatus according to at least one exemplary embodiment.

FIG. 7B is a cross-sectional view, from the same projection as FIG. 7A, of a common solder-sealable protective cap over and spaced above the sub-plurality of the MEMS devices, and a separate solder sealable protective cap over and spaced above at least one other of the MEMS devices, after the sacrificial layer has been removed.

FIG. 7C is a cross-sectional view, from the projection as FIGS. 7A and 7B, of an example in-process wafer-level MEMS structure in a process and related apparatus according to at least one exemplary embodiment, of a solder-sealed hermetically sealed protective cap over and spaced above the sub-plurality of the MEMS devices, and a separate solder-sealed hermetically protective cap over and spaced above at least one other of the MEMS devices.

FIG. 7D is a cross-sectional view, from the same projection as FIG. 7C, of singulated hermetically sealed MEMS devices, obtained from a singulation process.

FIG. 8 is a top view, from FIG. 7B projection 8-8, of example solder bump promoting structures on a protective cap layer overlaying an in-process MEMS structure, in an example process and structure according to at least one exemplary embodiment.

FIG. 9 shows a flow chart of one example wafer-level, liquid solder bath hermetic sealing of MEMS devices, in a wafer-level MEMS device packaging process according to at least one exemplary embodiment.

FIG. 10 shows one logical block schematic of one example display device having one example solder hermetically sealed MEMS interferometric display device according to one exemplary embodiment.

### DETAILED DESCRIPTION

Aspects of the invention are disclosed in the following description and related drawings directed to specific example embodiments of the invention. Alternate embodiments may be devised without departing from the scope of the invention. Additionally, well-known details of well-known structures and well-known techniques that may employed in combination with this disclosure to practice according to its exemplary embodiments may not be described in detail or may be omitted so as not to obscure novel aspects of the embodiments.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” in the context of a feature, advantage, mode of operation or the like a does not require that all embodiments of the invention include the discussed feature, advantage, mode of operation or the like.

The term “MEMs” as used herein encompasses, except in instances where it is explicitly stated otherwise or where it is made clear from the context to have a different meaning, all structures within the ordinary and customary meaning of “microelectromechanical systems” and/or “MEMS” including, but not limited to, structures having one or more microsensors, microactuators and/or microelectronics and, further, encompasses microoptoelectromechanical systems (MOEMS) and, further, encompasses both single microelectromechanical system and multiple microelectromechanical systems.

As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

The terms “hermetically sealed” and “hermetic seal,” as used herein in the context of a “hermetically sealed,” or “hermetic seal of a” device or interior space or volume of a device, means, except where explicitly stated otherwise or made clear from a particular context to have a different or narrower meaning, an interior space or volume sufficiently sealed to contain a given ambient state, where “given ambient state” may be any of a vacuum state or a given ambient fill of a given gas, liquid, and/or vapor(s), or mixture thereof, and to prevent escape, leakage or other egress of the given ambient fill, if any, and to prevent ingress of external environmental contaminants, e.g., external gas(ses), vapor(s), fluid(s) and/or particulate contamination, into the interior space or volume, sufficiently to maintain a pressure and purity of the given ambient condition within a tolerance and for a duration that would be understood, by persons of ordinary skill in the electronic device packaging arts, as within the range of tolerances and durations implied by the term “hermetically sealed” standing alone without description of a specific value of the tolerance or duration.

The term “wetting surface” is defined as encompassing, except in instances where explicitly stated otherwise or where made clear from its context to have a different or narrower meaning, the ordinary and customary meaning of “wetting surface” as understood by persons of ordinary skill in the soldering arts pertaining to electronic device packaging, and which includes, but is not limited to, a surface causing or tending to promote a lower “wetting angle” and/or tending to promote a capillary flow of a liquid solder and, where applicable, tending to promote the formation of intermetallic compounds at the interface between the wetting surface and the solder, with “wetting angle” defined according to its ordinary and customary meaning in such arts.

The term “non-wetting surface” is defined as encompassing, except in instances where explicitly stated otherwise or where made clear from its context to have a different or narrower meaning, the ordinary and customary meaning of “non-wetting surface” as understood by persons of ordinary skill in the soldering arts pertaining to electronic device packaging, and which includes, but is not limited to, a surface tending to promote a higher wetting angle and/or tending to substantially reduce or impede a capillary flow of a solder.

Specific examples will be described showing systems and methods according to one or more of the exemplary embodiments in relation to particular example shapes and types of MEMS devices, for example MEMS interferometric modulators. It will be understood, though, that these are only examples of the types of MEMS devices with which practices according to the exemplary are contemplated. Other examples include, but are not limited to: microelectromechanical switches, tunable switches, cantilever beam arrays, resonators, film bulk acoustic resonators (FBARs), FBAR filters, varactors, radio-frequency MEMS, hinged mirrors, pressure sensors, tunable capacitors, accelerometers, or combinations.

Processes according to one exemplary embodiment can start with an array or other plurality of MEMS devices fabricated on a wafer-level MEMS support substrate. The wafer-level MEMS support substrate may, for example silicon, (Si), glass, silicon-on-insulator (SOI), or silicon-germanium (SiGe). As one example, the wafer-level MEMS support substrate may be a large glass sheet. In one aspect, processes according to one exemplary embodiment can produce, for example, a plurality of individually packaged MEMS-based devices, by a novel wafer-level processing of the starting array or other plurality of MEMS devices to form, as will be understood, a temporary wafer-level MEMS structure on which each of the plurality of MEMS devices is individually hermetically sealed, by an individual protective cap particularly formed to be simply structured and integrated onto the substrate. This can be followed by a singulation of the temporary wafer-level MEMS structure, providing a plurality of individually hermetically sealed MEMS devices, each having an individual protective cap, hermetically sealing a MEMS device, integrated into the region of the substrate that supported that MEMS device during its fabrication.

As will be appreciated by persons of ordinary skill in the art from this disclosure, among various features provided by this and other aspects can be a substantial reduction in the number of processing operations when compared to conventional techniques and structures for hermetically sealed packaging of MEMS devices.

In an aspect of at least one exemplary embodiment, a sacrificial layer can be formed to overlay one or more of the plurality of MEMS devices. The sacrificial layer can, for example, be formed of a conventional MEMS sacrificial material such as, but not limited to, silicon (amorphous silicon or polycrystalline silicon), Mo, Ti, silicon dioxide or polymer. In one example according to this aspect, the sacrificial layer or a portion of the same can be configured as a temporary cap, formed of sacrificial material overlaying the one or more MEMS devices.

In an aspect a protective cap layer can be formed over the temporary cap that is formed of sacrificial materials. As will understood from examples described in greater detail at later sections, the material for the protective cap layer can be readily selected based, at least in part, on the particular sacrificial material selected for the temporary cap. As one illustration, in an example in which silicon dioxide is selected for the sacrificial material forming the temporary cap, an example protective cap layer can be, but is not limited to, silicon nitride. Furthermore, the protective cap layer can be formed by multiple layers of different materials to enhance its function. For example, multiple layers may be used to control the stress or to enhance the hermeticity by reducing the diffusivity of certain target gas through the protective cap materials.

In a further aspect, one or more solder sealable release ports or holes can be formed to extend through the protective cap layer, at a location on the protective cap layer aligned with an underlying temporary cap. As will be understood by persons of ordinary skill in the art from this disclosure, in accordance with one or more exemplary embodiments a function of the solder sealable release holes is to provide for ingress of a release agent, selected in accordance with the selected sacrificial material for the temporary cap. In an aspect the release agent is introduced according to process parameters, such as chemical formulation, flow rate, temperature, pressure, and duration that will remove the temporary cap, leaving the protective cap layer intact. The release agent can be liquid (e.g., KOH, TMAH, or HF), gas (e.g., XeF2), or plasma.

In an aspect, at least one or more solder-sealable release holes, having a solder-sealability according to various exemplary embodiments, can be formed through the protective layer. As will be described in greater detail at later sections, in one or more aspects according to various exemplary embodiments, the solder-sealable release holes are formed in a relative alignment with the underlying sacrificial layer caps, to provide for releasing agents, for example solvents, in a further aspect, to be introduced to remove the sacrificial layer caps. In a releasing aspect of various exemplary embodiments, introducing releasing agents into the solder-sealable release holes removes sacrificial material under the protective cap layer, in a direction progressing downward and progressing radially from the location the release hole. In a further aspect, the same release agent that is used to remove the sacrificial layer cap under the protective cap layer can be used to remove the sacrificial layer (or layers) for the MEMS structures, during the same release step, and this aspect can be further facilitated by selecting the materials for the sacrificial layer materials to have similar characteristics with respect to the release agent.

As previously described, in an aspect the solder-sealable release holes are formed in an alignment relative to the sacrificial layer caps and, as also previously described, in a related aspect the sacrificial layer caps can be formed in such that each covers, or overlays, a corresponding one or more of the plurality if MEMS devices supported in the wafer substrate. In combination with these aspects, and further to the above-mentioned releasing aspect, an introduction of releasing agents into the solder-sealable release holes can provide removal of sacrificial material under the protective cap layer at a region proximal to each of the solder-sealable releasing holes. In a related aspect, the releasing can continue until the MEMS devices previously overlaid by the sacrificial layer are exposed, i.e., released.

As will be appreciated by persons of ordinary skill in the art from this disclosure, when this sacrificial material under the protective cap layer at a region proximal to each of the solder-sealable releasing holes is removed to expose the MEMS device(s) that were overlaid by that sacrificial material, a remaining portion of the protective cap layer surrounding the solder-sealable releasing holes forming a ported, solder-sealable protective cap covering a now empty (with respect to sacrificial layer material) volume above the MEMS devices. In an aspect, and as will be further understood from the description in greater detail at later sections, the sacrificial layer caps and the solder-sealable releasing holes can be dimensioned and arranged so that, upon a completion of this releasing and its removal of the sacrificial layer under the release holes, the result is a wafer-level MEMS device structure, having a wafer substrate supporting a plurality of MEMS devices, with these MEMS devices now capped, in a selectable grouping, by one or more ported, solder-sealable protective caps.

In one aspect the solder-sealable ports may be additionally utilized for performing additional fabricating or finishing (e.g., releasing or coating) of the MEMS device under the ported MEMS protective cap, prior to a liquid solder bath sealing in accordance with one or more exemplary embodiments. In another aspect in accordance with one or more exemplary embodiments, a liquid solder bath sealing of the solder-sealable ports may be performed in a given ambient condition, (e.g., a vacuum or inert gas) to hermetically seal that given ambient condition in a chamber housing the MEMS device.

According to various exemplary embodiments, the ported MEMS protective cap may include a solder bump seal promoting structure for each of the solder-sealable ports. In one aspect, the solder bump seal promoting structure may comprise a solder flow promoting or “wetting” surface, for example a metallization layer, deposited or otherwise formed to surround, or substantially surround, the exterior port opening. In another aspect, a solder bump seal promoting structure may include a combination of a solder flow promoting structure as previously described and a solder flow inhibiting or constraining structure surrounding, or substantially surrounding, the solder flow promoting structure.

Methods and systems according to various exemplary embodiments provide a liquid solder bath hermetic sealing of all of the above-described solder-sealable ports in a single operation.

In an aspect, a liquid solder bath sealing can include releasably securing the wafer having the ported cap covered MEMS devices to a controllable immersion apparatus that positions the wafer above or otherwise proximal to a liquid solder bath. In one aspect, a controllable immersion apparatus provides motion of one or both of the wafer and the liquid solder bath over a range of positions, at a controllable rate, along a given axis. Further to the one aspect, the range of positions along the given axis includes a starting position above the liquid solder bath, a selected immersion position at which the solder bump seal promoting structure of the solder-sealable ports contacts and extends into the liquid solder bath to a desired immersion depth, immersion angle, and a process end position, which may for example be the starting position. For brevity, the cycle beginning at the starting position, moving to the immersion position, and moving to the process end position will be alternatively referenced as “the immersion cycle.”

In another aspect the wafer having the ported cap covered MEMS devices, releasably secured to the controllable immersion apparatus, can be completely immersed in the liquid solder bath.

According to various exemplary embodiments, a combination of the parameters defining the liquid solder bath condition, (e.g., solder type, temperature and viscosity), the parameters defining the solder sealable ports and their associated solder bump seal promoting structure (e.g., port diameter, and dimension, geometry, wetting properties of the solder bump seal promoting structure), and the parameters defining the immersion cycle, (e.g., the contacting, immersion depth, immersion angle, duration at the immersion depth, and rate of elevating or raising from the immersion depth) promotes an adhesion of the liquid solder to form, in the raising of the solder bump seal promoting structure and associated breaking of its contact with the liquid solder bath, a liquid solder mass sufficient to entirely cover the external opening of the solder sealable port, with an adhesion after hardening into a solder bump that forms, if desired, a hermetic seal.

It will be understood that the terms “elevating” and “raising” as used herein are to describe a change in distance along the given axis between the solder bump seal promoting structure and the liquid solder bath means to increase the distance, and “lowering” means to decrease the distance, irrespective of which of the solder bump seal promoting structure and the liquid solder bath is moved or is moving and which remains stationary.

As will be appreciated, among benefits of liquid solder bath sealing according to the exemplary embodiments is lower complexity processing, namely all of the ports sealed, in unison. Another benefit is increased yield and reliability, due to an inherently tighter uniformity in the soldering conditions across the plurality of solder-sealable ports.

In another aspect of various exemplary embodiments, a liquid solder bath sealing of the solder-sealable ports may hermetically seal any of conditions, e.g., pressure, humidity, mixture of gasses, or other gaseous environments, within the MEMS device chamber. For example, the liquid solder bath and controllable immersion apparatus can be within a processing vacuum chamber. The processing vacuum chamber can be evacuated to a desired vacuum, left at a normal atmospheric condition, or filled with a fill medium at a desired pressure condition which, via not yet sealed solder-sealable ports will also be established in the MEMS package ported chamber. The liquid solder bath immersion sequence described above can then be performed, thereby hermetically sealing the desired vacuum or other condition within the MEMS device chamber. Likewise, to fill and seal the MEMS device chamber with, for example, dry nitrogen with one atmosphere pressure, the liquid solder bath sealing process can be performed inside a glove box with the appropriate dry nitrogen environment. The amount of pressure that the MEMS device chamber can hold after performing the solder sealing will depend on diffusivity of gas through the protective cap layer and the vapor pressure of the solder bath, especially for sustaining lower vacuum levels.

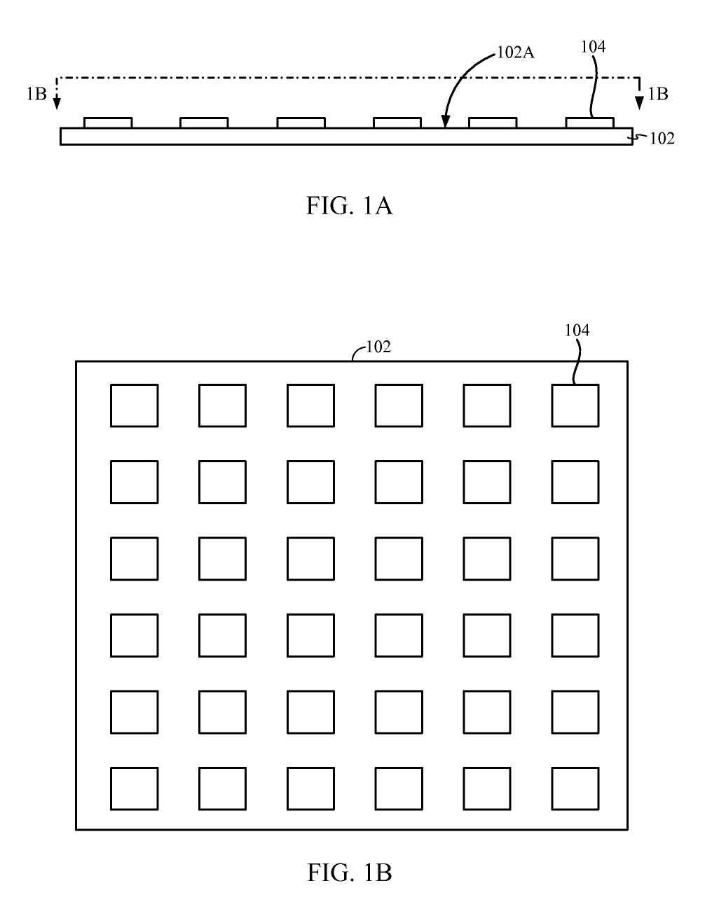

FIG. 1A is a side, cross-sectional view of one example wafer substrate 102 supporting a plurality of MEMS devices 104, from a projection normal to the major surface plane 102A of the wafer substrate 102, in example one process and apparatus according to at least one exemplary embodiment. FIG. 1B is a top view, from the FIG. 1A projection 1B-1B, of the FIG. 1A example wafer substrate 102 supporting the plurality of MEMS devices 104. With respect to the selection of the thickness and material for the MEMS support substrate 102, this may be according to conventional selection considerations and guidelines and, therefore, further detailed description is omitted. For example, as previously described, the MEMS support substrate 102 may, Si, glass (e.g., a large glass sheet), SOI, or SiGe. It will be noted that the major surface plane 102A is not a limitation on the scope of any embodiment and, instead, is only for providing a geometrically simple reference plane to describe examples without dense graphics that do not relate to concepts of the invention. For example, embodiments are contemplated in which a plurality of recesses (not shown) can be formed in the wafer substrate 102, with one or more of the recesses accommodating one or more MEMS devices. Persons of ordinary skill in the MEMS device packaging art can, from reading this disclosure, readily adapt its concepts to practice one or more of the embodiments with MEMS devices supported within recesses as described above, or on a wafer substrate having other irregular surface topography.

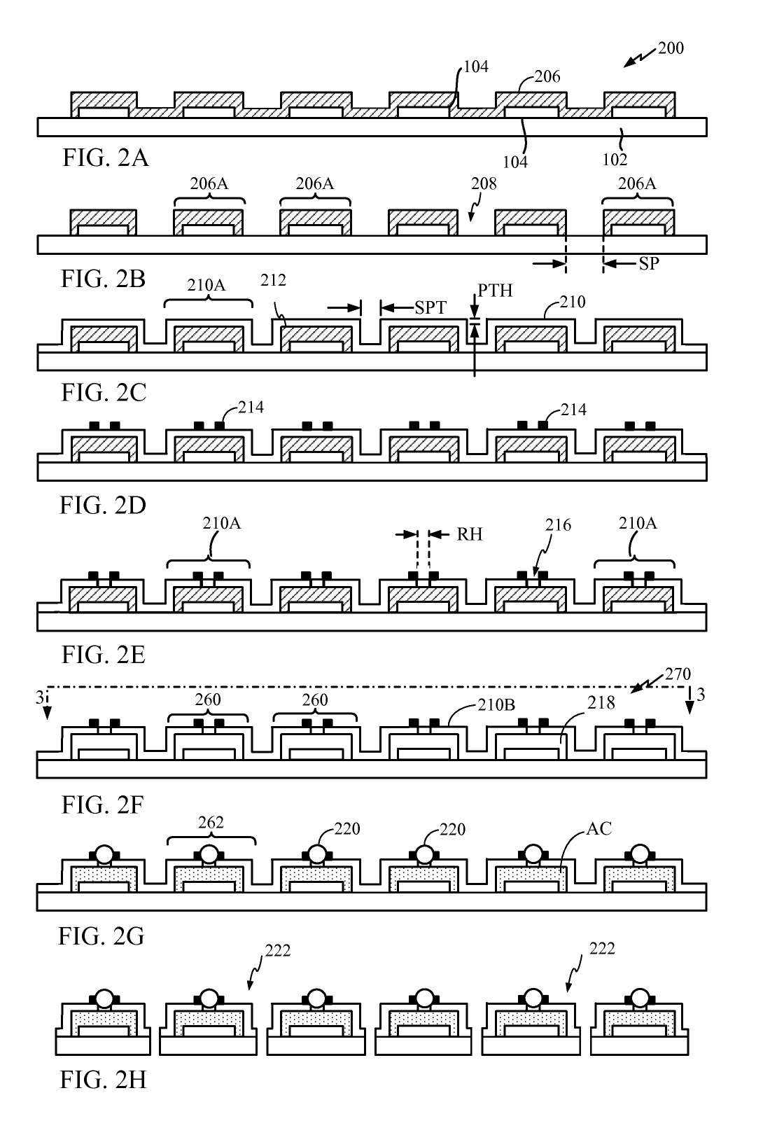

FIGS. 2A-2H show a snapshot history of one example wafer-level MEMS fabrication and hermetic packaging process 200 according to at least one exemplary embodiment, all viewed from the same cross-sectional projection normal to the major plane surface 102A of the FIG. 1A-1B wafer substrate 102. FIG. 2A shows depositing a sacrificial layer 206 over the FIG. 1A-1B array or other plurality of example MEMS devices 104, and ending at FIG. 2H with a plurality of individual hermetically sealed MEMS devices 222. As will be appreciated by persons of ordinary skill in the art from the described examples, among features and benefits of the various exemplary embodiments shown by the wafer-level MEMS fabrication and hermetic packaging process 200 are a significant reduction in the number of operations, with an immediately recognizable decrease in direct fabrication cost and increase in yield compared to conventional MEMS hermetically sealed packaging methods and means. As will also be appreciated by such persons from the described structures and operations, various exemplary embodiments shown by the wafer-level MEMS fabrication and hermetic packaging process 200 can further provide an inherent structural integrity not provided by conventional MEMS hermetically sealed packaging means. As will also be appreciated by such persons, another among various features and benefits of exemplary embodiments shown by the wafer-level MEMS fabrication and hermetic packaging process 200 is a low adoption cost that results from its uses, except in aspects otherwise described, of novel arrangements and combinations of known operations used elsewhere in conventional type MEMS fabrication.

Referring to FIG. 2A, one example wafer-level MEMS fabrication and hermetic packaging process 200 can begin by forming a sacrificial layer 206, with the thickness ranging from about 10 nanometers to few micrometers, overlaying the plurality of MEMS devices 104. The sacrificial layer 206 may be formed by, for example but not limited to, amorphous silicon (a-Si), polycrystalline silicon (poly-Si), Mo, Ti, W, silicon dioxide, or polymer. It will be understood that this is only an example, as alternative sacrificial materials will become apparent to persons of ordinary skill in the art from reading this disclosure. Considerations for the selection of the sacrificial material forming the sacrificial later 206 will be understood by such persons from reading this disclosure in its entirety, including the examples described in reference to FIGS. 2A-2H. Particular among the considerations that will be understood by such persons is that releasing operations, such as described below in reference to FIGS. 2E and 2F, dissolve or otherwise remove the sacrificial material forming the sacrificial layer 206. Persons of ordinary skill in the art will understand that selection of the specific material for the sacrificial layer 206, and selection of other fabrication materials and parameters relating to the releasing operation, for example the chemical composition of the releasing agent, as well as the desired dimensions and quantities of the FIG. 2E solder-sealable release holes 216 that are described in greater detail below. Furthermore, persons of ordinary skills in the art will understand upon reading this disclosure that these chemical compositions, dimensions and quantities are preferably selected such that interaction between the releasing agent and MEMS and surrounding structures will not compromise the structures intended to be kept intact throughout the release process.

Referring to FIG. 2B, in one aspect a wafer-level MEMS fabrication and hermetic packaging process 200 can include an etching or other micromachining operation (not shown) that may be performed on the sacrificial layer 206 to form singulation reliefs 208 between adjacent MEMS devices 104. In an aspect, singulation reliefs (not shown) may be formed co-planar with, and extending perpendicular to, the singulation relief 208, and may be arranged and dimensioned likewise.

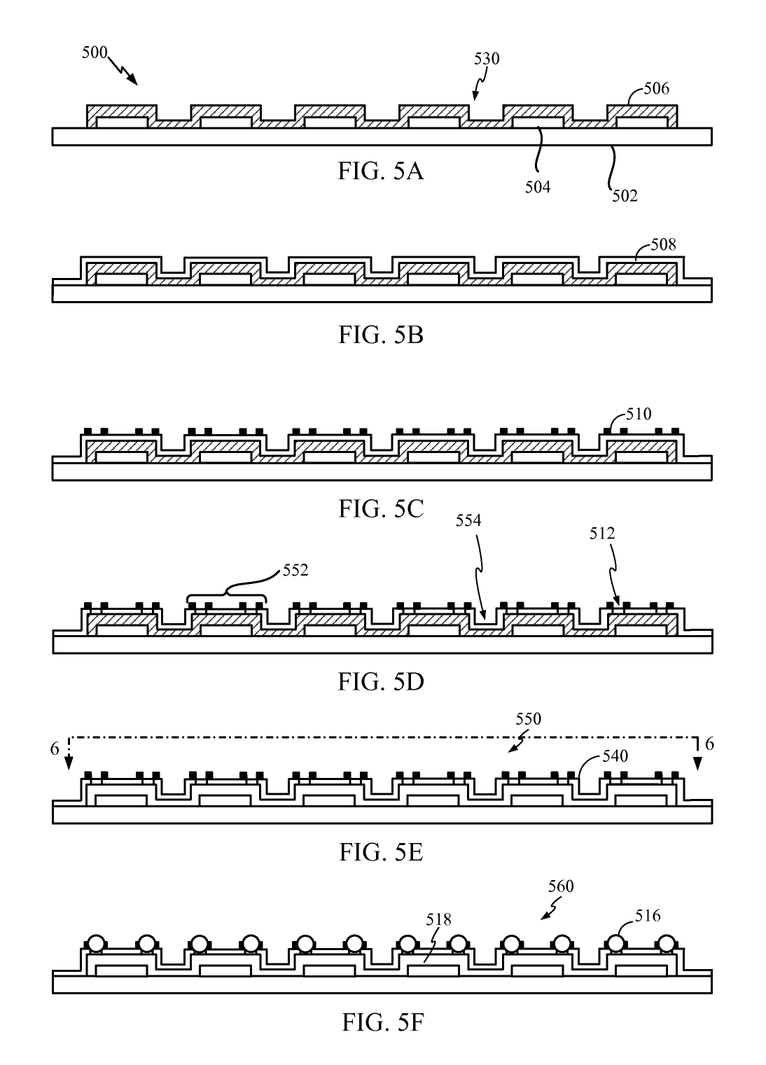

In a further aspect, as shown by FIG. 2B, the singulation reliefs 208 can be configured to leave portions of the sacrificial layer 206 as temporary caps 206A, each overlaying or covering one or more of the MEMS devices 104. The specific example shown at FIG. 2B has each temporary cap 206A covering one MEMS device 104. In other aspects, as will be described in greater detail in reference to FIGS. 5A-5F and elsewhere, singulation reliefs such as 208 are omitted, or are formed only at specific boundaries between regions of MEMS devices (not shown in FIG. 2B). The result, as will be described, is that a sacrificial layer such as the FIG. 2A example sacrificial layer 206 will remain to form what will be termed as “shared temporary caps” (not shown in FIGS. 2A-2H), each covering two or more of the MEMS devices.

Referring still to FIG. 2C, the singulation reliefs 208 can have a width SPT. As will be understood from the description below, the width SPT can provide for singulation such as will be described in reference to FIG. 2H. In addition to the singulation requirements, persons of ordinary skills in the art will be able to determine the dimensions of SPT based on the pertinent parameters including the requirements for structural integrity of the protective cap 210, for electrical connections between MEMS structures inside and outside of the final packaged devices, and for isolation between MEMS devices inside and the protective cap walls.

FIG. 2C is a cross-sectional view, from the same projection as FIG. 2B, showing a protective cap layer 210 having a plurality of protective cap regions 210A, each protective cap region 210A overlaying a corresponding temporary cap 206A. In one example, an interstitial region 212 of the protective cap layer 210 may extend across the singulation reliefs 208. The protective cap layer 210 may be formed of a material resistant to the release agent later used to dissolve the underlying temporary cap 206A. One example material for the protective cap layer 210, which may be selected if silicon dioxide is the sacrificial material forming the sacrificial layer 206 can be, for example, silicon nitride.

Referring still to FIG. 2C, the protective cap layer 210 may have a thickness PTH. With respect to the value or range of values of PTH, as will be described in greater detail at later sections, in one aspect a wafer-level MEMS fabrication and hermetic packaging process 200 will have a release operation that removes the temporary caps 206A under the protective cap regions 210A. As a result the volume that was occupied by the temporary caps 206A will be become a chamber, with the protective cap region formed on the now-removed temporary cap 206A becoming a protective cap (not shown in FIG. 2C). As will be understood, the protective cap can be dome-like or hat-like structure, having the thickness PTH. In addition, the protective cap layer 210 can be of an arbitrary topology that follows the topology of the sacrificial layer 206 that, in turn, follows the topology of the MEMS structure 104. The thickness PTH, as will be understood by a person of ordinary skill in the art reading this disclosure, can therefore be selected with consideration to mechanical forces that may act on the protective cap. The characteristics of such mechanical forces, and therefore the thickness PTH may, in significant part, be application specific. However, given a particular application, these mechanical forces are readily determinable by persons of ordinary skill in the art by applying conventional engineering principles and know-how such persons possess to this disclosure and, therefore, further detailed description is omitted.

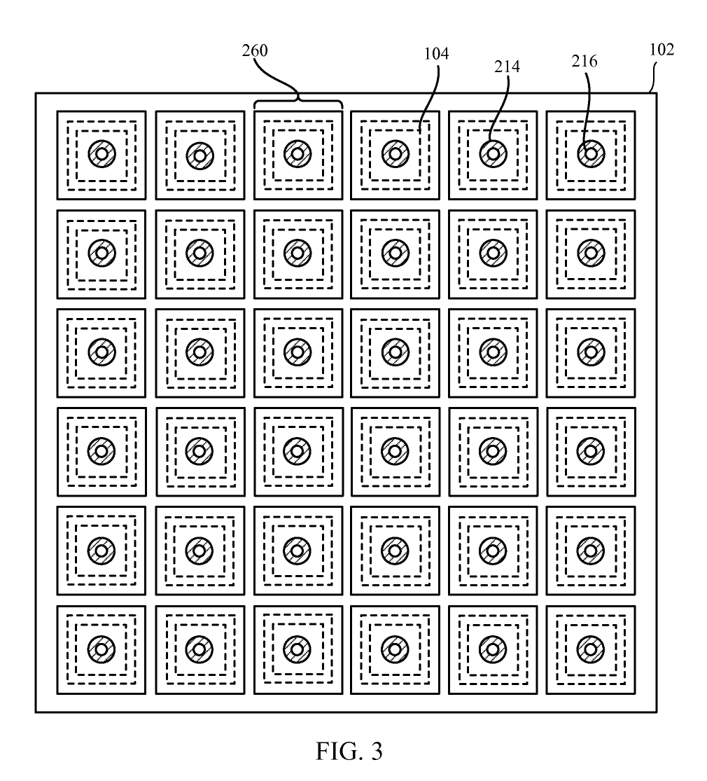

FIG. 2D is a cross-sectional view, from the same projection as FIG. 2C, showing solder-wetting surfaces or solder bump seal promoting structures 214 disposed on or otherwise formed on exposed, top surfaces of the protective layer cap regions 210A. An example form of the solder bump seal promoting structures 214 is an annular ring as will be described in greater detail in reference to FIGS. 2E and 3.

FIG. 2E is a cross-sectional view, from the same projection as FIG. 2D, showing solder-sealable release holes 216 formed in alignment with the solder bump seal promoting structures 214. Each solder-sealable release hole 216 extends through the protective cap layer 210 into the underlying sacrificial layer 206. In the FIG. 2E example, the solder-sealable release holes 216 and solder bump seal promoting structures 214 are aligned with the protective layer cap regions 210A. As previously described, the solder bump seal promoting structure 214 can, for example, comprise an annular ring and, in one aspect, can surround the external opening (shown but not separately numbered) of the solder-sealable release holes 216. Each solder bump seal promoting structure 214 is configured, and is formed of suitable wetting surface materials that function, in accordance with methods and systems of various exemplary embodiments described in greater detail at later sections, to promote a particular flow and adhesion of solder to seal the solder-sealable release holes 216 formed, as shown in FIG. 2E, after the solder bump seal promoting structures 214 shown at FIG. 2D are formed.

Referring to FIGS. 2D and 2E, as will be understood, the material and the geometry for the solder bump seal promoting structure 214 can be, in part, a design choice, in combination with application-specific parameters such as the type of solder chosen for the solder sealing that is described in greater detail at later sections. The material and the geometry for the solder bump seal promoting structure 214 can be readily selected by persons of ordinary skill in the art, combining conventional know-how of soldering technology in combination with the entirety of the present disclosure.

FIG. 2F is cross-sectional view, from the same projection as FIG. 2E, showing an in-process wafer-level MEMS device 270, having a plurality of solder-sealable ported caps 260, each covering and spaced above at least one MEMS device 104 on the wafer substrate 102, obtained by a removing the sacrificial material (temporary cap 206A) under the solder-sealable release holes 216, in example process and related apparatus according to at least one exemplary embodiment.

FIG. 3 is a top view, from FIG. 2F projection 3-3. Referring to FIG. 3, in one aspect exposed top surfaces (shown and labeled “210B” on FIG. 2F) of the solder sealable ported caps 260 not covered by the solder bump seal promoting structure 214 may be a solder flow inhibiting or constraining surface, in other words as one of its surface characteristics it may be non-wetting with respect to solder. In aspects using a solder flow inhibiting or constraining surface on the exposed top surfaces 210B, implementation is not necessarily by a structure separate from, e.g., deposited on, the protective cap layer 210 forming the solder sealable ported caps 260. The solder flow inhibiting or constraining surface can, for example, be a surface quality of the material selected for the protective layer 210 and therefore present at areas where the solder bump seal promoting structure 214 is absent.

FIG. 2G is a cross-sectional view, from the same projection as FIG. 2F, of a plurality of non-singulated hermetically sealed MEMS devices 262 supported on the wafer substrate 102, obtained by forming solder bumps 220 that hermetically seal the solder-sealable release holes 216 of the solder-sealable ported protective caps 260, in an example process and related apparatus according to at least one exemplary embodiment.

FIG. 2H is a cross-sectional view, from the same projection as FIG. 2G, of a plurality of hermetically sealed MEMS devices 222, obtained from a singulation process on the non-singulated hermetically sealed MEMS devices 262, in an example process and related apparatus according to at least one exemplary embodiment.

Referring to FIGS. 2A-2H, it will be understood that for purposes of coupling the

MEMS devices 104 to the outside world there may, for example, be electrical traces (not shown) formed on the wafer substrate 102 to extend under the solder-sealable ported protective caps 260, and/or vias (not shown) formed to extend through regions of the protective cap layer 210 forming the solder-sealable ported protective caps 260. Persons of ordinary skill in the art, having view of this disclosure, can readily adapt conventional trace and via means to obtain such coupling and, therefore, further detailed description is omitted.

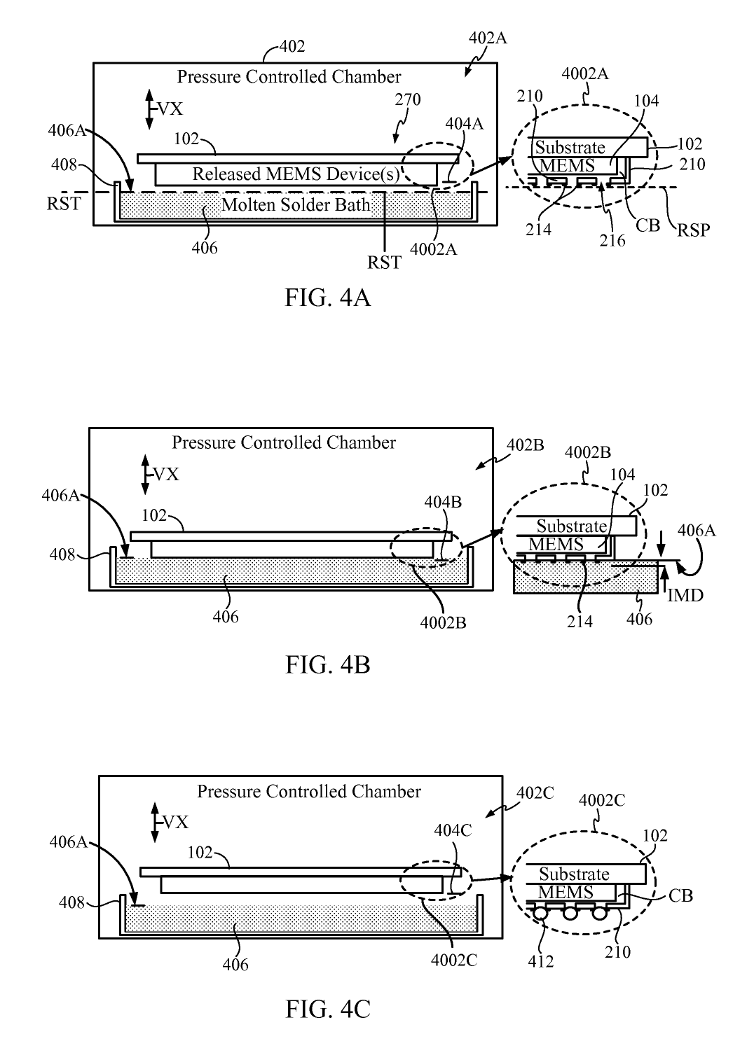

FIGS. 4A, 4B, and 4C show three snapshots from one example process time history of an example liquid solder bath sealing process according to one or more exemplary embodiments, of solder sealable release holes formed through one or more protective caps on a wafer substrate according to the exemplary embodiments. The example liquid solder bath sealing process shown by the FIGS. 4A, 4B, and 4C show an example process performed in a controlled pressure chamber 402 and are described, for purposes of illustration, as operating with the FIG. 2F example in-process wafer-level MEMS device 270. FIGS. 4A, 4B and 4C show, respectively, the FIG. 2F example in-process wafer-level MEMS device 270 at an example starting position 404A, solder immersion position 404B, and ending position 404C with respect to a liquid solder bath 406 having a top surface 406A. The process history represented by the FIGS. 4A-4C snapshots will be referenced for brevity in description as an “immersion cycle.”

It will be understood that the example immersion cycle shown by FIGS. 4A-4C is shown with, and described in reference to the FIG. 2F example in-process wafer-level MEMS device 270 only to assist in understanding concepts by providing reference to a previously disclosed example structure, and is not intended to limit to practices according to the embodiments to only such structures. For example, as will described in greater detail in reference to FIGS. 5E and 5F below, a liquid solder bath sealing according to the FIGS. 4A-4C immersion cycle can be employed to hermetically seal the release holes 512 of the FIG. 5D example in-process wafer-level MEMS device 550 to form the FIG. 5E hermetically sealed wafer-level MEMS device 560.

It will be further understood that FIGS. 4A, 4B, and 4C show the FIG. 2F example in-process wafer-level MEMS device 270 being supported and moved to the positions 404A, 404B and 404C by a movable support apparatus (not explicitly shown). It will be appreciated that the movable support apparatus can employ, for example, servo motors (not shown) controlled by a conventional servo motor controller (not shown). Such a movable support can be readily implemented by persons of ordinary skill in the art having view of the present disclosure and, therefore, further detailed description of the structure of the movable support apparatus is omitted.

Referring to FIG. 4A, the liquid solder bath 406 shown in the controlled pressure chamber 402 can be contained within, for example, a pan or tub 408, referenced hereinafter as the “liquid solder pan” 408. The liquid solder pan 408 may be formed of any metal(s), alloy or other material having temperature characteristics and chemical properties compatible with the solder chosen for the liquid solder bath 406. The liquid solder pan 408 may, for example, be titanium. One example implementation for the liquid solder pan 408 can be an off-the-shelf liquid solder bath apparatus, available from various commercial vendors. It will be understood that the previously described movable support apparatus can, in one aspect, raise, lower, and/or laterally move the liquid solder pan 408 to effectuate the relative positions of the in-process wafer-level MEMS device 270 and the liquid solder bath depicted at FIGS. 4A-4C.

With respect to the specific solder for the liquid solder bath 406, this can be in part a design choice, based on considerations readily determined by persons of ordinary skill in the art having view of this disclosure and desiring to practice the embodiments in association with a particular application. For example, the liquid solder bath 406 may be an Indium, or other lead free solder alloy. Example considerations for the liquid solder bath 406 include the viscosity versus temperature characteristics, the diameter of the solder-sealable release holes 216, and the geometry, dimensions and wetting characteristics of the wetting surface portion of the solder bump seal promoting structures 214.

Referring to FIGS. 4A-4C, in one aspect the immersion cycle can be performed within the depicted controlled pressure chamber 402, in combination with a particular controlling of the pressure. Example methods according to this aspect are described below in greater detail. It will understood, however, that pressure control is only one aspect of liquid solder bath sealing in methods according to the various exemplary embodiments and, therefore, one example immersion cycles without pressure control will be first described.

Referring to the FIG. 4A enlarged view 4002A, in the starting position 404A (and in the immersion position 404B as described below), the MEMS wafer is positioned such that the solder bump seal promoting structures 214 are, according to one aspect, substantially coplanar, along a plane RSP that is substantially parallel to the plane RST of the top surface 406A of the liquid solder bath 406. As will be understood, according to this aspect, the co-planar orientation of the solder bump promoting structures 214 in the plane RSP, and RSP being parallel to RST, provides for all of the solder bump seal promoting structures 214 to be brought into a simultaneous contact with, and to be simultaneously removed from contact with, the liquid solder bath 406. However, embodiments are not limited to the plane RSP being parallel with the plane RST. For example, depending on various application-specific parameters value defining the shape and dimensions of the in-process wafer-level MEMS device 270, simultaneous contact of all of the solder bump promoting structures 214 with the top surface 406A of the liquid solder bath 406, as will occur if RSP is closely parallel to RST may, possibly, promote air pockets forming proximal to solder bump seal promoting structures 214 of the solder-sealable release holes 216. Such potential air pockets may, possibly, partially obstruct or otherwise interfere with contact of the liquid solder with the solder bump seal promoting structures 214 and/or the external openings of the solder-sealable release holes 216 that the solder bump seal promoting structures 214 surround. Therefore, in one aspect, the in-process wafer-level MEMS device 270 may be supported such that the plane RSP is at an angle (not shown in FIGS. 4A-4C) with respect to the plane RST. Further to this aspect, the angle of RSP and RST may be, but is not limited to being, anywhere from, for example, approximately a few degrees up to and including, for example, approximately 90 degrees. In a variation of this aspect, the immersion angle can be up to approximately 180 degrees, meaning the wafer can be immersed with the solder sealable release holes 216 facing away from the solder bath 406. Still further to this general aspect of immersion angle, the angle may be arbitrary. It will be understood that in practices according to this aspect the depth of the liquid solder bath should be sufficient to allow full immersion of the in-process wafer-level MEMS device 270, particularly all of its solder bump seal promoting structures 214 and the external openings of the solder-sealable release holes 216 that the solder bump seal promoting structures 214 surround.

Referring to FIG. 4A, a controllable immersion apparatus (not explicitly shown) attaches to one or both of the MEMS package support and the liquid solder bath 406 to provide motion, along the axis VX of one or both of the ported package MEMS device 270 and the liquid solder bath 406 over a range of positions spanning at least the positions 404A, 404B and 404C illustrated at FIGS. 4A-4C, at a controllable rate.

Referring to the FIG. 4B enlarged view 4002B, in one example immersion cycle the immersion apparatus moves the FIG. 2F in-process wafer-level MEMS device 270 downward (or moves the liquid solder pan 408 upward) to bring the solder bump seal promoting structure 214 of the solder-sealable release holes 216 into contact with the top surface 406A of the liquid solder bath 406 and stop at an immersion position 404B at which the solder bump seal promoting structure 214 is at a desired immersion depth IMD depth. In one aspect, one example immersion cycle maintains the immersion position 404B for an immersion duration that adequately heats the solder bump seal promoting structures 214 for proper solder bond

Referring to the FIG. 4C enlarged view 4002C, after maintaining the FIG. 2F in-process wafer-level MEMS device 270 at the previously described immersion position 404B for given duration, the immersion apparatus is controlled to elevate or raise the solder bump seal promoting structures 214 out of and away from the liquid solder bath 406 until these reach the process ending position 404C. This elevation or raising (or lowering of the liquid solder pan 408) can be performed at a particular rate over the time history beginning with the solder bump seal promoting structures 214 being level with the top surface 406A of the liquid solder bath 406 to the instant at which a solder mass on the solder bump seal promoting structures 214 separates from the liquid solder bath 406. As will be understood by persons of ordinary skill in the art from this disclosure, this particular rate is based on the viscosity of the liquid solder, the geometry and materials of the solder seal bump promoting structure 214.

With continuing reference to FIG. 4C, either during movement to the process ending position 404C or shortly thereafter, the liquid solder masses that flowed onto and adhered to the solder bump seal promoting structures 214 solidified to form solder bump hermetic seals 412 over each of the solder-sealable release holes 216. The solder bump hermetic seals 412 may be an example of the FIG. 2G solder bump seals 220.

In another aspect, as previously described, an example liquid solder batch solder sealing such as described in reference to FIGS. 4A-4C may be performed within a controllable ambient condition chamber, such as the example controlled pressure chamber 402. In one aspect, the controlled pressure chamber 402 may have a starting pressure condition 402A when in the FIG. 4A starting position 404A, and may then be evacuated, or pressurized with, for example, an inert gas, to a desired MEMS chamber condition 402B prior to being moved to the immersion position 404B. Then, during the movement from the immersion position 404B to the process ending position 404C, the solder masses form and harden to the solder bump hermetic seals 412 and the vacuum or other condition at 402B is hermetically sealed within the MEMS clearance chamber CB. The controlled pressure chamber 402 can then be re-pressurized or re-filled to a condition 402C, which may be the same as the starting condition 402A. It will be appreciated that the hermetic seal quality obtained from the solder bump hermetic seals 412 formed through the various exemplary embodiments will likely provide a higher quality, longer life expectancy hermetic seal than may be obtained using conventional sealing means.

Referring to FIGS. 2F and 2G, it will be understood that alternative embodiments are contemplated that can provide solder sealing of the FIG. 2F release holes to form the in-process wafer-level MEMS device 270.

For example, in one previously described aspect, the FIG. 2F in-process wafer-level

MEMS device 270 may be fully immersed in a liquid solder bath while supported at an arbitrary orientation. As will be understood by persons or ordinary skill in the art, in view of the present disclosure, a diameter RH for the solder-sealable release holes 216 and a viscosity for the solder (not shown) in the solder bath may be selected such that the liquid solder will not flow through the solder-sealable release holes 216 to contaminate the MEMS devices 104.

As another example, in one aspect a solder-spraying (not shown) may be used in place of a liquid solder bath to form the FIG. 2G solder bumps 220. In practicing embodiments with the solder spraying aspect, a pressure and viscosity of the solder spray, rate of spray, spray particle sizes, and diameter RH of the solder-sealable release holes 216 can be readily determined persons or ordinary skill in the art, in view of the present disclosure, such that the solder spray will not flow through the solder-sealable release holes 216 to contaminate the MEMS devices 104.

FIGS. 5A-5F show a snapshot history of another example wafer-level MEMS fabrication and hermetic packaging process 500 according to at least one exemplary embodiment, all viewed from the same cross-sectional projection normal to the major plane of wafer substrate 502, starting at FIG. 5A with depositing a sacrificial layer 506 over an array or other plurality of example MEMS devices 504, and ending at FIG. 5F with a wafer-level hermetically sealed MEMS device 560.

FIG. 5A is a cross-sectional view showing one example in-process wafer-level MEMS structure 530 obtained from an aspect of forming, in an example process and related apparatus according to another exemplary embodiment, at least one sacrificial layer 506 overlaying the example plurality of MEMS devices 504 on a wafer substrate 502.

FIG. 5B is a cross-sectional view, from the same projection as FIG. 5A, showing one example common protective cap layer 508 overlaying the common sacrificial layer, in an example process and related apparatus according to another exemplary embodiment.

FIG. 5C is a cross-sectional view, from the same projection as FIG. 5B, showing example solder bump promoting structures (wetting surfaces) 510 on the common protective cap layer 508 overlaying the common sacrificial layer 506, in an example process and related apparatus according to at least one exemplary embodiment. Regions of the common sacrificial layer 506 on the MEMS devices 504 are elevated relative to regions of the common sacrificial layer 506 that are directly on the substrate 502. Likewise, areas of the protective cap layer 508 overlaying the elevated regions of the common sacrificial layer 506 are elevated relative to other areas of the protective cap layer. As will be described in greater detail in reference to FIG. 5D, at a later processing stage the elevated regions of the common protective layer will be referred to as ported common cap regions 552. As will be understood, the ported common cap regions 552 are comparable, to an extent, to the ported cap regions 210A described in reference to FIGS. 2D and 2E. It will be appreciated, though, from FIG. 5E that the common cap regions 552 differ from the FIG. 2D ported cap regions 210A in that the FIG. 5D common sacrificial layer 506, when removed as shown at FIG. 5E, will produce a continuous, shared chamber such as the FIG. 5F shared chamber 518.

Referring now to FIG. 5D, this is a cross-sectional view, from the same projection as FIG. 5C, showing solder-sealable release holes 512 through the common protective cap layer 508. In the FIG. 5D example, the solder-sealable release holes 512 are aligned with the common cap regions 552 and extend to the underlying common sacrificial layer 506 over the plurality of MEMS devices 504 on a wafer substrate 502.

Referring still to FIG. 5D, it will be understood that the alignment of the solder-sealable release holes 512 and solder bump seal promoting structures 510 with the common cap regions 552 is only an example. Other alignments are contemplated. Further, embodiments are contemplated that can include solder bump seal promoting structures 510 and solder-sealable release holes 512 formed in regions 554 between the common cap regions 552. Referring back to FIGS. 4A-4C, it will be understood that liquid solder hermetic sealing, according to one or more exemplary embodiments, using solder bump seal promoting structures 510 and solder-sealable release holes 512 formed in regions 554 between the common cap regions 552 may include variations on the previously described immersion depth, and/or immersion orientation, to obtain a good solder bump seal (not shown in the figures) adhesion.

FIG. 5E is a cross-sectional view, from the same projection as FIG. 5D, showing one example in-process wafer-level MEMS structure 550 having a wafer-level protective cap 540 obtained from a releasing operation through the solder-sealable release holes 512, removing the common sacrificial layer under the FIG. 5D common protective cap layer 508, in an example process and related apparatus according to at least one exemplary embodiment.

FIG. 5F is a cross-sectional view, from the same projection as FIG. 5E, of one example hermetically sealed wafer-level MEMS device 560, obtained from hermetically sealed solder bumps 516 formed by a solder sealing according to at least one exemplary embodiment of the solder-sealable release holes 512, in an example process and related apparatus according to at least one exemplary embodiment.

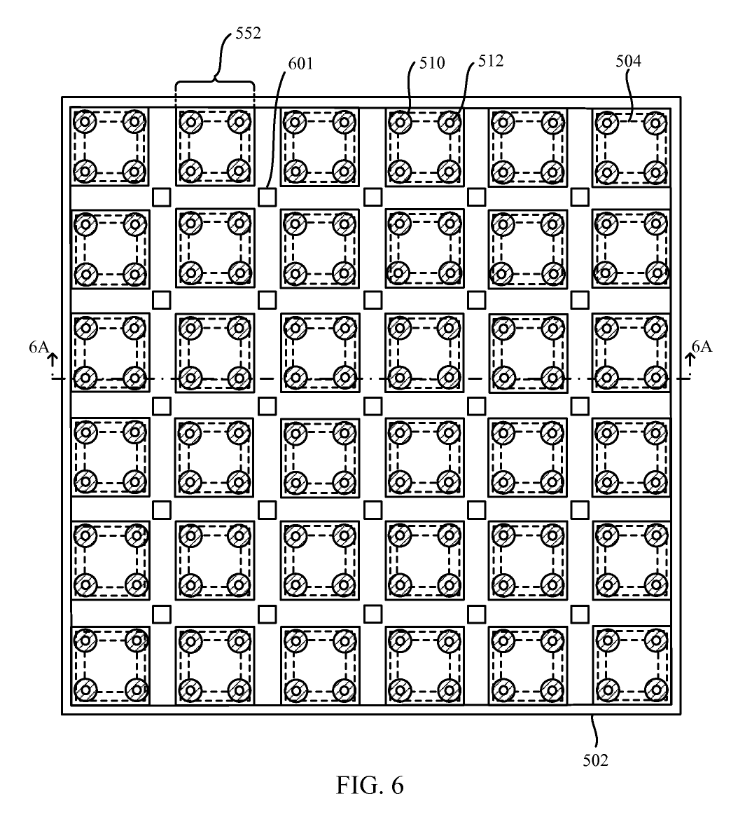

FIG. 6 is a top view, from FIG. 5E projection 6-6, of the example solder bump promoting structures 510 on the common cap regions 552 of the protective cap layer 508, surrounding the solder-sealable release holes 512, in an example process and structure according to at least one exemplary embodiment. Alternatively, the cut across line 6A of FIG. 6 is the cross-section depicted in FIGS. 5A to 5F. According to this cross-section, the protective cap layer 508 is continuous over the plurality of MEMS devices 504 and may not provide the required structural integrity, especially for low pressure sealing. One method to address this problem is to add anchor areas to provide the necessary structural rigidity. In the anchor 601 shown in FIG. 6, the protective layer 508 bonds to the substrate 502 directly because the sacrificial layer 506 is removed in the same manner that the singulation gap 208 in FIG. 2B is defined. Adding the anchors 601 in-between the MEMS devices 504 will provide the necessary structural rigidity that will keep the protective cap 508 from collapsing.

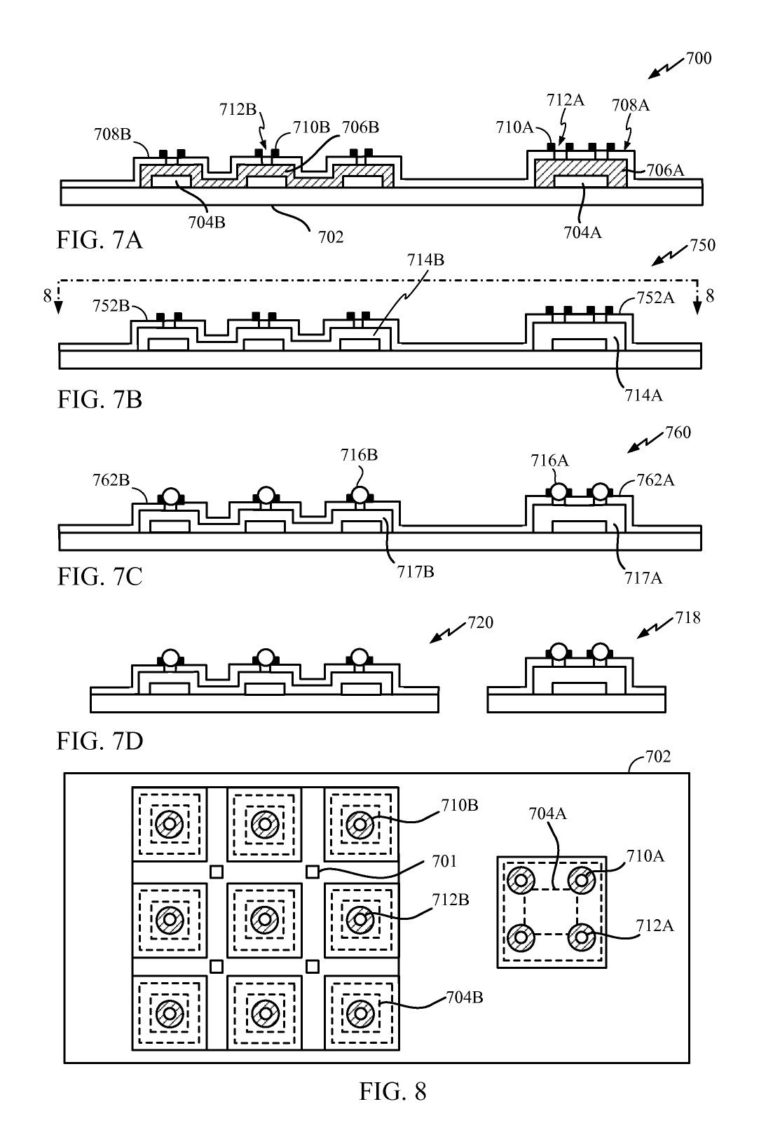

FIG. 7A is cross-sectional view of an example in-process wafer-level MEMS structure 700 in an example process and related apparatus according to at least one exemplary embodiment, from a projection normal to a major plane of a wafer substrate 702. The FIG. 7A in-process wafer-level MEMS structure 700 has the wafer substrate 702 supporting a plurality of MEMS devices 704A, 704B, with a common sacrificial layer 706B overlaying the MEMS devices 704B, and another sacrificial layer 706A overlaying one or more of the MEMS devices 704A. Further, in an aspect, a common protective cap layer 708B overlays the common sacrificial layer 706B and another protective cap layer 708A overlays the other sacrificial layer 706A. In addition, at least one solder bump seal promoting structure 710B is formed on an exposed surface of the common protective cap layer 708B, in an alignment with a corresponding release hole 712B through the common protective cap layer 708B to its underlying common sacrificial layer 706B. Likewise, at least one solder bump seal promoting structure 710A is formed on an exposed surface of the common protective cap layer 708B, in an alignment with a corresponding release hole 712A through the protective cap layer 708A to its underlying other sacrificial layer 706A.

FIG. 7B is cross-sectional view, from the same projection as FIG. 7A, showing one example in-process wafer-level MEMS structure 750 having a ported, solder-sealable common protective cap 752B over the MEMS device 704B, obtained from a releasing operation through the release holes 712B, removing the common sacrificial layer 706B, leaving a chamber or void 714B, in an example process and related apparatus according to at least one exemplary embodiment. The example in-process wafer-level MEMS structure 750 also has, formed concurrent with releasing that produced the ported, solder-sealable common protective cap 752B, a ported, solder-sealable protective cap 752A over at least one MEMS device 704A, obtained from a releasing operation through the release holes 712A, removing the other sacrificial layer 706A and leaving a chamber or void 714A.

FIG. 7C is a cross-sectional view of an example in-process wafer-level MEMS structure 760, from the same projection as FIG. 7B, in an example process and related apparatus according to at least one exemplary embodiment, of hermetically sealed common protective cap 762B, formed by solder bumps 716B hermetically sealing the release holes 712B, spaced by a chamber 717B over the MEMS device 704B, and a separate solder-sealed hermetically protective cap 762A, formed by solder bumps 716A hermetically sealing the release holes 712A, over and spaced by a chamber 717A above at least one other of the MEMS devices 704A.

FIG. 7D is a cross-sectional view, from the same projection as FIG. 7C, of singulated hermetically sealed MEMS devices 718 and 720, obtained from a singulation process on the FIG. 7C in-process MEMS structure 760

FIG. 8 is a top view, from FIG. 7B projection 8-8, of example solder bump promoting structures on a protective cap layer overlaying an in-process MEMS structure, in an example process and structure according to at least one exemplary embodiment. The anchor areas 701 are shown on the multiple MEMS device 704B with a common protective cap, which provide structural rigidity for the protective cap.

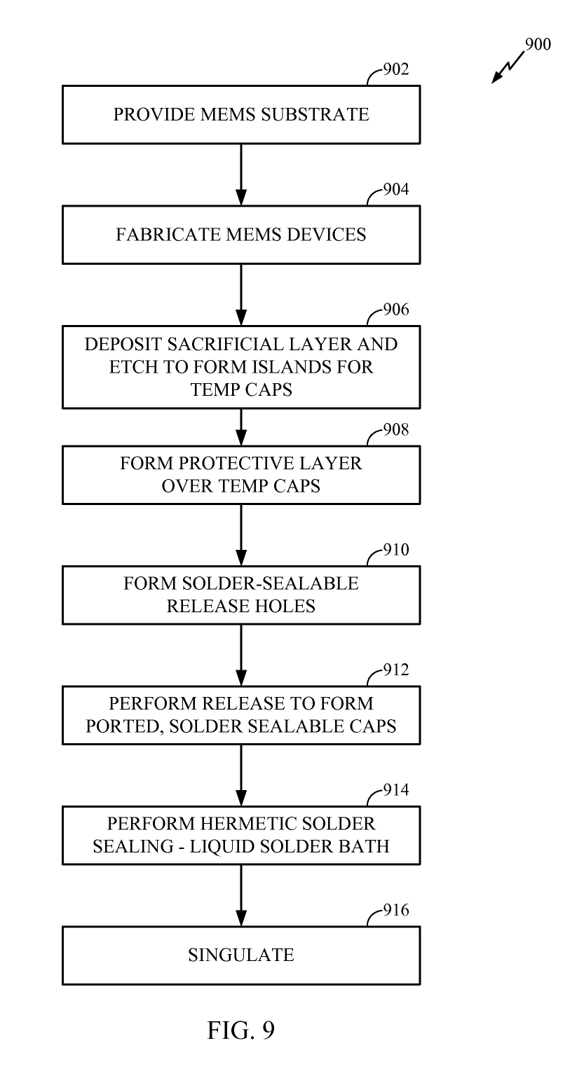

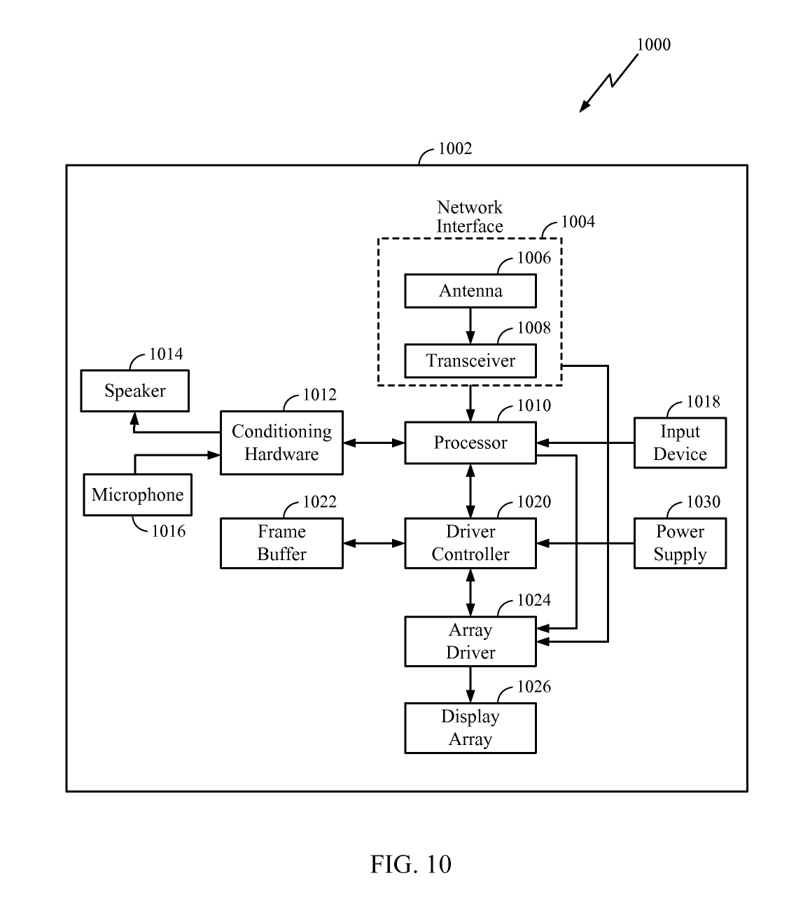

FIG. 9 shows a logical flow diagram of one example wafer-level MEMS fabrication and hermetic sealing process 900 according to one exemplary embodiment. Referring to FIG. 9, in one example wafer-level MEMS fabrication and hermetic sealing process 900, at 902 a MEMS support substrate is provided, for example the FIGS. 1A-1B example MEMS wafer substrate 102 and then, at MEMS device fabrication 904, a plurality of MEMS devices can be fabricated on the MEMS support substrate. Referring to FIGS. 1A, 1B and 9 together, an example MEMS device fabrication 904 can be the MEMS devices 104 formed on the wafer substrate 102. An example wafer-level MEMS fabrication and hermetic sealing process 900 then goes to 906 to deposit and form a sacrificial layer into temporary caps over the MEMS devices formed at 904. Referring to FIGS. 9, 2A and 2B together, one example 906 depositing and forming a sacrificial layer into temporary caps over the MEMS devices can be the forming of the sacrificial layer 206 and etching of the singulation relief 208, forming a plurality of temporary caps 206A. Referring to FIGS. 9 and 5A together, another example 906 depositing and forming a sacrificial layer into temporary caps over the MEMS devices formed at 904 can be the forming of the sacrificial layer 506, without an etching of singulation reliefs, to form single common temporary cap (i.e., the entire sacrificial layer 506) over all of the MEMS devices 104.

Continuing to refer to FIG. 9, in one example according to the wafer-level MEMS fabrication and hermetic sealing process 900 after the 906 forming a sacrificial layer into temporary caps over the MEMS devices, at 908 a protective layer may be formed over the temporary caps. Referring to FIGS. 9 and 2C together, one example 908 forming of a protective layer over the temporary caps formed at 906 can be the protective cap layer 210 forming the protective cap regions 210A. Referring to FIGS. 9 and 5B together, another example 908 forming of the protective layer over the temporary caps formed at 906 can be the forming of the common protective cap layer 508. It will be appreciated by persons of ordinary skill in the art, having view of this disclosure, that some portions or areas of the protection layer can be used as singulation area or as anchors.

Referring still to FIG. 9, after the 908 forming a protective layer, one example of the wafer-level MEMS fabrication and hermetic sealing process 900 can go to 910 and form solder-sealable release holes through the protective layer, at locations aligned with the temporary caps. Referring to FIGS. 9, 2D, 2E and 3 together, one example 910 forming of solder-sealable release holes through the protective layer can be the forming of the solder bump promoting structures 214, on surfaces of the protective layer cap regions 210A, followed by forming of the solder-sealable release holes 216, aligned with the solder bump promoting structures. Referring to FIGS. 9, 5C, 5D and 6 together, another example 910 forming of solder-sealable release holes through the protective layer can be the forming of the solder bump seal promoting structures 510, at a plurality of locations on the common protective cap layer 508, followed by forming of the plurality release holes 512 through the common protective cap layer 508, each release hole 512 aligned with a solder bump seal promoting structure 510.

Referring still to FIG. 9, after the 910 forming of solder-sealable release holes through the protective layer formed at 908, one example of the wafer-level MEMS fabrication and hermetic sealing process 900 can go to 912 and perform a releasing that removes the temporary caps formed at 906, to form one or more solder-sealable, ported protective caps on the wafer substrate, each covering one or more of the MEMS devices. One example of a releasing at 912 is the releasing described in reference to FIGS. 2E and 2F, forming the in-process wafer level device 270. Another example is the releasing described in reference to FIGS. 5D and 5E, forming the in-process wafer-level MEMS device 550. In one aspect the releasing at 912 can include, or provide a releasing (not separately shown) of the MEMS devices 104 or 504, using the same release chemistry used to remove the sacrificial layer formed at 904. In another aspect, a releasing of the MEMS devices 104 or 504 (not separately shown) can use another chemistry compatible with the chemistry used at 912.

Continuing to refer to FIG. 9, after the 912 releasing forming of one or more solder-sealable, ported protective caps on the wafer substrate, one example of the wafer-level MEMS fabrication and hermetic sealing process 900 can go to 914 and perform a hermetic solder sealing of the solder-sealable, ported protective caps formed at 912, to form one or more hermetically sealed MEMS devices on the wafer substrate. One example hermetic solder sealing 914 can be the immersion liquid solder bath solder sealing described in reference to FIGS. 4A-4C. Another example can be a full immersion liquid solder bath sealing, and another example can a solder spraying, with parameters chosen to form solder bumps sealing the release holes, without solder passing the through release holes and contaminating the underlying MEMS devices.

Continuing to refer to FIG. 9, after the 914 hermetic solder sealing 912, one example of the wafer-level MEMS fabrication and hermetic sealing process 900 can go to 916 and singulate the hermitically sealed devices

FIG. 10 shows one logical block schematic of one example display device 1000 having one example solder hermetically sealed MEMS interferometric display device according to one exemplary embodiment. The illustrated exemplary display device 1000 includes a housing 1002 supporting various internal as well as exposed, or partly exposed components. In one aspect, the exemplary display device 1000 includes a network interface 1004 that may have an antenna 1006 coupled to a transceiver 1008. The transceiver 1008 can be coupled to a processor 1010, which is coupled to conditioning hardware 1012. The conditioning hardware 1012 may be configured to condition a signal (e.g., filter a signal), and is coupled to a speaker 1014 and a microphone 1016. The processor 1010 is also coupled to an input device 1018 and a driver controller 1020. The driver controller 1020 is coupled to a frame buffer 1022 and to an array driver 1024, which in turn is coupled to a display array 1026. The display array 1026 can be implemented as a MEMS device, such as the above-described MEMS device 104, supported on a MEMS support substrate such as the example wafer substrate 102, and sealed within a liquid solder bath sealed ported MEMS protective cap, such as the FIG. 5 example ported package MEMS device shown at FIGS. 3A and 3B after, for example, a liquid solder bath sealing such as described in reference to FIGS. 4A-4C, according to one or more exemplary embodiments. A power supply 1030 provides power to all components as required by the particular exemplary display device 1000 design.

The above-described network interface 1004, with the antenna 1006 and the transceiver 1008, allow the display device 1000 to communicate with one or more devices (not shown) over a network (not shown). The network interface 1004 may also have processing capabilities to relieve requirements of the processor 1010. The antenna 1006 can be any conventional antenna for transmitting and receiving signals and, for example, may transmit and receive radio frequency (RF) signals according to the IEEE 802.10 standard, including IEEE 802.10(a), (b), or (g), and/or according to the BLUETOOTH standard. In the case of a cellular telephone, the antenna 1006 can be configured to receive CDMA, GSM, AMPS, or other known signals for communicating within a wireless cell phone network.

The transceiver 1008 can be configured to pre-process the signals received from the antenna 1006 for further processing by the processor 1010. The transceiver 1008 can also process signals received from the processor 1010 for transmittal from the exemplary display device 1000 via the antenna 1006.

In one alternative embodiment, the transceiver 1008 can be replaced by a receiver. In yet another alternative embodiment, network interface 1004 can be replaced by an image source (not explicitly shown), for example a digital video disc (DVD) or other storage device, that store and sends image data to the processor 1010.

Processor 1010 can be configured to control the overall operation of the exemplary display device 1010. The processor 1010 can be configured to receive data, such as the above described compressed image data from the network interface 1004 or an image source, and process the data into raw image data or into a format that is readily processed into raw image data. The processor 1010 then sends the processed data to the driver controller 1020 or to frame buffer 1022 for storage. Raw data can include information that identifies the image characteristics at each location within an image, for example color, saturation, and gray-scale level. Conditioning hardware 1012 can, for example, include amplifiers and filters (not shown) for transmitting signals to the speaker 1014, and for receiving signals from the microphone 1016. Conditioning hardware 1012 may be discrete components within the exemplary display device 1000, or may be incorporated within the processor 1010 or other components.

The driver controller 1020 can be configured to take raw image data generated by the processor 1010, either directly from the processor 1010 or from the frame buffer 1022, and reformat the raw image data for high speed transmission to the array driver 1024. The driver controller 1020 can be configured to reformat the raw image data into a data flow having a raster-like format, with a time order suitable for scanning across the display array 1026. The driver controller 1020 can then send the formatted information to the array driver 1024. The driver controller 1020 can be associated with the processor 1010 as a stand-alone Integrated Circuit (IC) and, one aspect, may be embedded in the processor 1010 as hardware, embedded in the processor 1010 as software, or fully integrated in hardware with the array driver 1024.

In one aspect, the array driver 1024 receives the formatted information from the driver controller 1020 and reformats the video data into a parallel set of waveforms that are applied many times per second to the hundreds and sometimes thousands of leads coming from the display's x-y matrix of pixels. In one aspect, the driver controller 1020 can be a bi-stable display controller (e.g., an interferometric modulator controller) and, likewise, the array driver 1024 can be a bi-stable display driver (e.g., an interferometric modulator display). In one aspect, the driver controller 1020 can be integrated with the array driver 1024, as is known in conventional highly integrated systems such as cellular phones, watches, and other small area displays.

The input device 1018 provides for a user to control the operation of the exemplary display device 1000 and may, for example be a keypad, such as a QWERTY keyboard or a telephone keypad, a button, a switch, a touch-sensitive screen, or a pressure- or heat-sensitive membrane. In one aspect, the microphone 1016 is an input device for the exemplary processor 1010, for receiving voice commands from a user for controlling operations of the exemplary display device 1000.

The power supply 1030 can include a variety of energy storage devices as are well known in the art. For example, the power supply 1030 can be a rechargeable battery, such as a nickel-cadmium battery or a lithium ion battery. In one aspect, the power supply 1030 can be a renewable energy source, a capacitor, or a solar cell including a plastic solar cell, and solar-cell paint. In another aspect, the power supply 1030 can be configured to receive power from a wall outlet.

In some embodiments, control programmability resides, as described above, in a driver controller which can be located in several places in the electronic display system. In some embodiments, control programmability resides in the array driver 1024. Those of skill in the art will recognize that the above-described optimizations may be implemented in any number of hardware and/or software components and in various configurations.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A method for hermetically sealing an opening at an exterior surface of a device to an interior volume of the device, comprising:
forming a wetting surface on a region of the exterior surface of the device adjacent the opening; and
immersing the wetting surface into a viscous fluid to draw a portion of the viscous fluid sufficient to cover and hermetically seal the opening.

2. The method of claim 1, wherein the device includes a cap having an interior surface facing the interior volume and the opening is a port extending through the cap to the interior volume.

3. The method of claim 1, wherein the device includes a substrate having an upper surface forming at least a portion of the exterior surface, wherein the exterior surface surrounding the opening is a surface of the substrate, and wherein the wetting surface is disposed on the upper surface.

4. The method of claim 3, wherein the substrate is a wafer.

5. The method of claim 1, wherein the device is a microelectromechanical systems (MEMS) device.

6. The method of claim 1, wherein the wetting surface is a metal.

7. The method of claim 1, wherein the opening has a given diameter, and wherein the method further comprises selecting a viscosity of the viscous fluid based, at least in part, upon said diameter.

8. The method of claim 1, wherein immersing the wetting surface into a viscous fluid is performed in an environment having a given low pressure substantially lower than a normal atmospheric pressure.

9. The method of claim 8, wherein hermetically sealing the opening seals a space under the opening at the given low pressure.

10. The method of claim 1, wherein immersing the wetting surface into a viscous fluid is performed in a partial vacuum environment.

11. The method of claim 10, wherein hermetically sealing the opening the hermetically seals a space under the opening at the partial vacuum environment.

12. The method of claim 1, wherein immersing the wetting surface into a viscous fluid is performed in a pressure environment having a pressure not less than one atmosphere.

13. The method of claim 12, wherein hermetically sealing the opening the hermetically seals a space under the opening at the pressure not less than one atmosphere.

14. The method of claim 1, wherein immersing the wetting surface into a viscous fluid is performed in a selected environment having a selected gas or mixture of gasses at a selected pressure.

15. The method of claim 14, wherein hermetically sealing the opening the hermetically seals the selected environment under the opening.

16. The method of claim 1, wherein immersing the wetting surface into a viscous fluid includes immersing the wetting surface to a given depth in a viscous fluid bath, and includes withdrawing the wetting surface from the viscous fluid bath with the portion of the viscous fluid hermetically sealing the opening.

17. The method of claim 16, wherein the given depth totally immerses the device in the viscous fluid bath.

18. The method of claim 17, wherein the given depth partially immerses the device in the viscous fluid bath.

19. The method of claim 1, wherein the viscous fluid is solder and the viscous fluid bath is a solder bath, wherein the wetting surface is immersed to a given depth in the solder bath, and wherein the immersing includes withdrawing the wetting surface from the solder bath with a solder portion hermetically sealing the opening.

20. The method of claim 19, wherein the solder bath includes a lead free alloy.

21. The method of claim 20, wherein the lead free alloy is Indium or Indium alloy.

22. The method of claim 19, wherein immersing the wetting surface into the solder bath is performed in an environment having a given low pressure substantially lower than a normal atmospheric pressure.

23. The method of claim 22, wherein hermetically sealing the opening seals a space under the opening at the given low pressure.

24. The method of claim 19, wherein immersing the wetting surface into a viscous fluid is performed in a partial vacuum environment.

25. The method of claim 24, wherein hermetically sealing the opening the hermetically seals a space under the opening at the partial vacuum environment.

26. The method of claim 19, wherein immersing the wetting surface into a viscous fluid is performed in a pressure environment having a pressure not less than one atmosphere.

27. The method of claim 26, wherein hermetically sealing the opening the hermetically seals a space under the opening at the pressure not less than one atmosphere.

28. The method of claim 19, wherein immersing the wetting surface into a viscous fluid is performed in a selected environment having a selected gas or mixture of gasses at a selected pressure.

29. The method of claim 28, wherein hermetically sealing the opening the hermetically seals the selected environment under the opening.

30. A method for packaging a device supported on a substrate, comprising:
forming a device on a wafer-level substrate;
forming a sacrificial layer over the device;
forming a protective layer over the sacrificial layer;
forming a solder-sealable release hole through the protective layer to the sacrificial layer;
forming a ported cap from a portion of the protective layer proximal to the solder-sealable release hole, by introducing a releasing agent through the release hole to remove sacrificial layer material under the solder-sealable release hole to form a space under the portion of the protective layer; and
solder sealing the solder-sealable release hole to form a hermetically sealed cap covering the space.

31. The method of claim 30, wherein forming the solder-sealable release hole comprises:
forming a wetting surface on an exposed surface of the protective layer; and
forming a release hole through the protective layer to the sacrificial layer, in an alignment with the wetting surface.

32. The method of claim 31, wherein said solder sealing includes spraying a solder onto the wetting surface.

33. The method of claim 31, wherein said solder sealing the release hole includes
immersing the release hole in a liquid solder bath to form a solder bump sealing the release hole.

34. The method of claim 33, wherein the immersing includes supporting the wafer-level substrate above the liquid solder bath, lowering the wafer level substrate into the liquid solder bath to a depth immersing the wetting surface in the solder bath, and raising the wafer-level substrate to raise the wetting surface from the solder bath.

35. The method of claim 31, wherein forming the solder-sealable release hole comprises:
forming a solder bump seal promoting structure on an exposed surface of the protective layer; and
forming a release hole through the protective layer, in an alignment with the solder bump seal promoting structure.

36. The method of claim 30, wherein the forming the device on a wafer-level substrate includes forming a plurality of devices on the wafer-level substrate,
wherein forming the protective layer forms the protective layer to have a plurality of protective cap layer regions, each protective cap layer region overlaying corresponding portion of the sacrificial layer over a corresponding one or more of the plurality of devices,
wherein forming the solder-sealable release hole includes forming at least one solder-sealable release hole through each of the protective cap layer regions to the sacrificial layer, and
wherein forming the ported cap includes forming a plurality of ported caps, each having a portion of one of the protective cap layer regions proximal to a corresponding one or more of the solder-sealable release holes, and
wherein the solder sealing solder includes sealing each of the solder-sealable release holes at each of the plurality of the ported caps to form a corresponding plurality of hermetically sealed caps, each covering a corresponding space.

37. The method of claim 36, wherein the forming the devices forms the devices as MEMS devices.

38. The method of claim 36, wherein the solder sealing is performed in an environment having a given low pressure substantially lower than a normal atmospheric pressure.

39. The method of claim 38, wherein the solder sealing hermetically seals the space under each hermetically sealed cap at the given low pressure.

40. The method of claim 36, wherein the solder sealing is performed in a partial vacuum environment.

41. The method of claim 40, wherein hermetically sealing the opening the hermetically seals the space under each hermetically sealed cap at the partial vacuum environment.

42. The method of claim 36, wherein the solder sealing is performed in a pressure environment having a pressure not less than one atmosphere.

43. The method of claim 42, wherein hermetically sealing the opening the hermetically seals the space under each hermetically sealed cap at the pressure not less than one atmosphere.

44. The method of claim 36, wherein said solder sealing is performed in a selected environment having a selected gas or mixture of gasses at a selected pressure.

45. The method of claim 44, wherein hermetically sealing the opening the hermetically seals the selected environment in the space under each hermetically sealed cap.

46. The method of claim 36, wherein forming at least one solder-sealable release hole at each of the protective cap layer regions each of the solder-sealable release hole comprises:
forming a wetting surface on an exposed surface of each of the protective cap layer regions; and
forming a release hole in an alignment with the wetting surface on the exposed surface of each of the protective cap layer region, the solder-sealable release hole extending through the protective cap layer to a sacrificial layer.

47. The method of claim 46, wherein said solder sealing includes spraying a solder onto the wetting surfaces.

48. The method of claim 46, wherein said solder sealing includes forming a solder bump seal, solder bonded to each of the wetting surfaces, to seal the solder-sealable release hole that is aligned with the wetting surface.

49. The method of claim 48, wherein forming the solder bump seal includes immersing the wetting surfaces in a liquid solder bath, and raising the wetting surface from the liquid solder bath.

50. The method of claim 49, wherein immersing the wetting surfaces in a liquid solder bath includes contacting all of the wetting surfaces substantially simultaneously with a top surface of the liquid solder bath.

51. The method of claim 49, wherein forming a wetting surface on an exposed surface of each of the protective cap layer regions forms the wetting surfaces in a common plane, and wherein immersing the wetting surfaces in a liquid solder bath includes contacting at least one of the wetting surfaces with a top surface of the liquid solder while the common plane is at a given angle with respect to the common plane of the top surface.

52. The method of claim 36, wherein forming at least one solder-sealable release hole at each of the protective cap layer regions each of the solder-sealable release hole comprises:
forming a solder bump seal promoting structure on an exposed surface of each of the protective cap layer regions; and
forming a release hole in an alignment with the solder bump seal promoting structure on the exposed surface of each of the protective cap layer regions, the release hole extending through the protective cap layer to the sacrificial layer.

53. The method of claim 52, wherein said solder sealing includes spraying a solder onto the solder bump seal promoting structures.

54. The method of claim 52, wherein said solder sealing includes forming a solder bump seal, solder bonded to each solder bump seal promoting structure, to seal the release hole that is aligned with the solder bump seal promoting structure.

55. The method of claim 54, wherein forming the solder bump seal includes immersing the solder bump seal promoting structures in a liquid solder bath, and raising the solder bump seal promoting structures from the liquid solder bath.

56. The method of claim 55, wherein immersing the solder bump seal promoting structures in a liquid solder bath includes contacting all of the solder bump seal promoting structures substantially simultaneously with a top surface of the liquid solder bath.

57. The method of claim 55, wherein forming the solder bump seal promoting structure on the exposed surface of each of the protective cap layer regions forms the solder bump seal promoting structures in a common plane, and wherein immersing the solder bump seal promoting structures in a liquid solder bath includes contacting at least one of the solder bump seal promoting structures with a top surface of the liquid solder bath while the common plane is at a given angle with respect to the c common plane of the top surface.

58. A releasable and hermitically sealable wafer-level apparatus comprising:
a substrate;
a plurality of devices supported on the substrate;
a sacrificial layer formed on and covering each of the plurality of devices;
a protective cap layer formed on the sacrificial layer to extend over at least one of the plurality of devices, and having an exposed surface, the protective cap layer including a release hole extending from an opening on the exposed surface to the sacrificial layer; and
a wetting surface on the exposed surface, surrounding the opening of the release hole.

59. The apparatus of claim 58, wherein the at least one of the plurality of devices over which the sacrificial layer extends is a MEMS device.

60. A wafer-level structure comprising:
a wafer-level substrate;
a plurality of devices supported on the wafer-level substrate;
at least one protective cap defining a hermetically sealed space for a corresponding one or more of the plurality of devices, each protective cap having a peripheral base surrounding the corresponding one or more of the plurality of devices and that is deposition bonded to the wafer-level substrate, and each protective cap having a cap region extending from the peripheral base and above the corresponding one or more of the devices, wherein each cap region forms a release hole, and wherein each cap region has an external surface supporting a wetting surface proximal to the release hole and a solder bump seal solder bonded to the wetting surface.

61. The wafer-level structure of claim 60, wherein the peripheral base of the at least one protective cap is surface bonded to the wafer-level substrate.
